(19) United States
(12) Patent Application Publication
(10) Pub. No.: US 2010/0238058 A1
(43) Pub. Date: Sep. 23, 2010

(54) MULTIPLE INPUT ANALOG TO DIGITAL CONVERTER

(75) Inventor: John B. Scaduto, Caldwell, NJ (US)

Correspondence Address: STANDLEY LAW GROUP LLP, 6300 Riverside Drive, Dublin, OH, 43017, US

(73) Assignee: Ohaus Corporation, Pine Brook, NJ (US)

(21) Appl. No.: 12/726,197

(22) Filed: Mar. 17, 2010

Related U.S. Application Data
(60) Provisional application No. 61/160,964, filed on Mar. 17, 2009.

(51) Int. Cl. H03M 1/00

(52) U.S. Cl. 341/141

(57) ABSTRACT

A multi-input analog to digital converter (“ADC”) to accept and process multiple inputs. The analog multiplexer is integrated with an amplifier chopper circuit to form a high precision, temperature stable, ADC circuit with multiple inputs.

### CROSS-REFERENCE TO RELATED APPLICATION

This application claims the priority benefit of U.S. Provisional Patent Application No. 61/160,964, filed Mar. 17, 2009, which is hereby incorporated by reference in its entirety.

### BACKGROUND OF THE INVENTIVE FIELD

The present invention is directed to a multi-input analog to digital converter (“ADC”) to accept and process multiple inputs. In the preferred embodiment, an analog multiplexer is integrated with an amplifier chopper circuit to form a high precision, temperature stable, ADC circuit with multiple inputs. The present invention can be used with various applications including accepting inputs from multiple load cells that require high precision amplification over a wide range of temperatures.

### SUMMARY OF THE GENERAL INVENTIVE CONCEPT

In the preferred embodiment, an analog multiplexer is integrated with an amplifier chopper circuit to form a high precision, temperature stable, ADC circuit with multiple inputs.

### BRIEF DESCRIPTION OF THE DRAWINGS

In addition to the features mentioned above, other aspects of the present invention will be readily apparent from the following descriptions of the drawings and exemplary embodiments, wherein like reference numerals across the several views refer to identical or equivalent features, and wherein:

FIG. 1 illustrates one embodiment of the circuit of the present invention;

FIG. 2A illustrates a diagram of one embodiment of the connections between the multiple load scales and the multiplexers;

FIG. 2B illustrates one embodiment of the amplifier circuit of the present invention;

FIG. 3 illustrates one embodiment of a traditional circuit with separate amplifier circuits;

FIG. 4 illustrates one embodiment of the multiplexer inputs of the present invention;

FIG. 5 illustrates another embodiment of the invention for low resolution applications;

FIG. 6 illustrates an example of a Wheatstone bridge circuit.

### DETAILED DESCRIPTION OF EXEMPLARY EMBODIMENT(S)

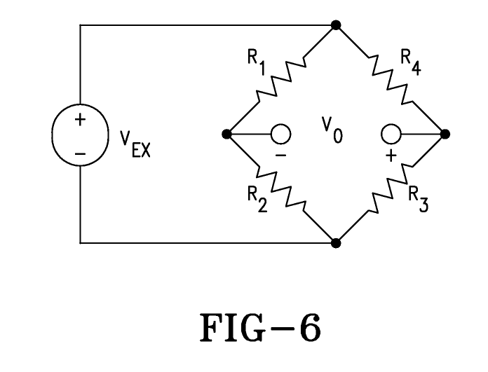

In the presence of strain, the resistance of the strain gauge changes. Generally, the gauges mounted on the spring are connected in a Wheatstone bridge circuit, as shown in FIG. 6. Load cells typically use four strain gauges in a Wheatstone bridge configuration. The bridge outputs a differential signal proportional to the applied force. Because the changes in strain are extremely small (and resistance), additional circuitry is needed to amplify the changes in resistance.

The output voltage of the bridge, V_{O}, is equal to:

$${V}_{O} = [ \frac{{R}_{3}}{{R}_{3} + {R}_{4}} - \frac{{R}_{2}}{{R}_{1} + {R}_{2}} ] \cdot {V}_{EX}$$

In order to accurately measure the input from a load cell (e.g., weight where the load cell is part of a weight scale), a scale terminal must be able to resolve a very small analog voltage with a high level of precision over a wide temperature range. The circuit that accomplishes this is called an Analog to Digital Converter (ADC). Typically, the ADC in a scale terminal may be required to resolve 100,000 divisions from an input of 10 millivolts while remaining stable from −10 C to 40 C ambient temperature range.

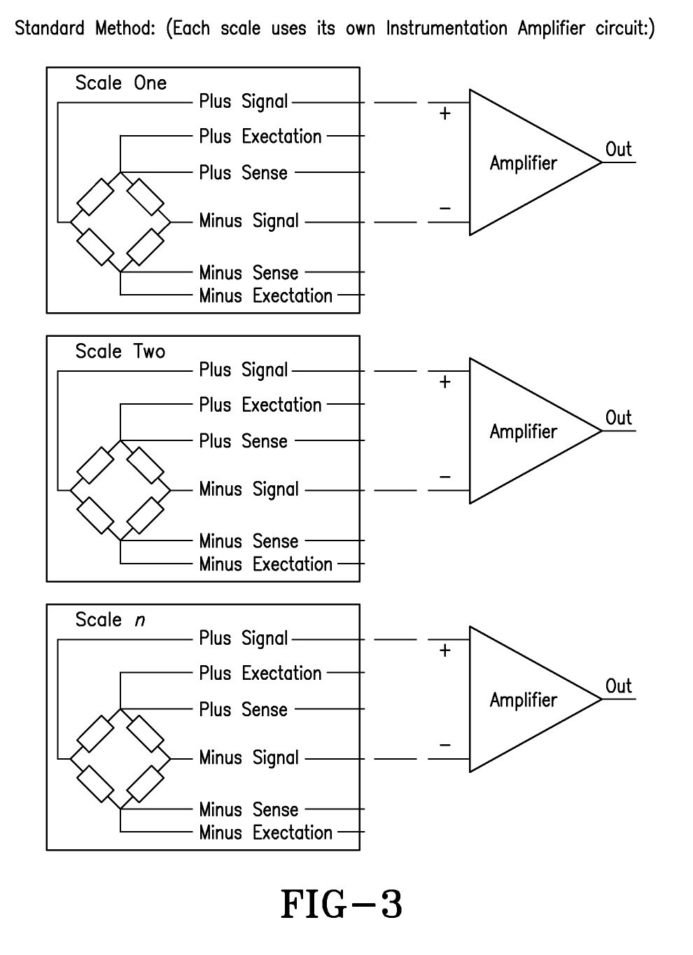

For some applications, it is desirable to have more than one load cell (scale) connected to the indicator so that the operator can switch between two or more weighing platforms at the touch of a button. Usually, this is done by building an entire second amplifier and/or ADC converter circuit, as shown in FIG. 3. This approach adds considerable cost per input since the parts required for the ADC section(s) are expensive, precision components. This invention is the modification of an ADC (in the preferred embodiment a high precision sigma-delta ADC) to accept and process multiple inputs.

Precision ADC converters commonly use the chopper technique in order to reduce drift and noise inherent in the electronic components that comprise them. In less demanding situations, devices called analog multiplexers (switches) are used to allow several channels of an analog signal to be measured by a single ADC circuit; however, they are not accurate or stable enough for high precision applications. By integrating the analog multiplexer with the amplifiers chopper circuit, a high precision ADC circuit with multiple inputs was achieved.

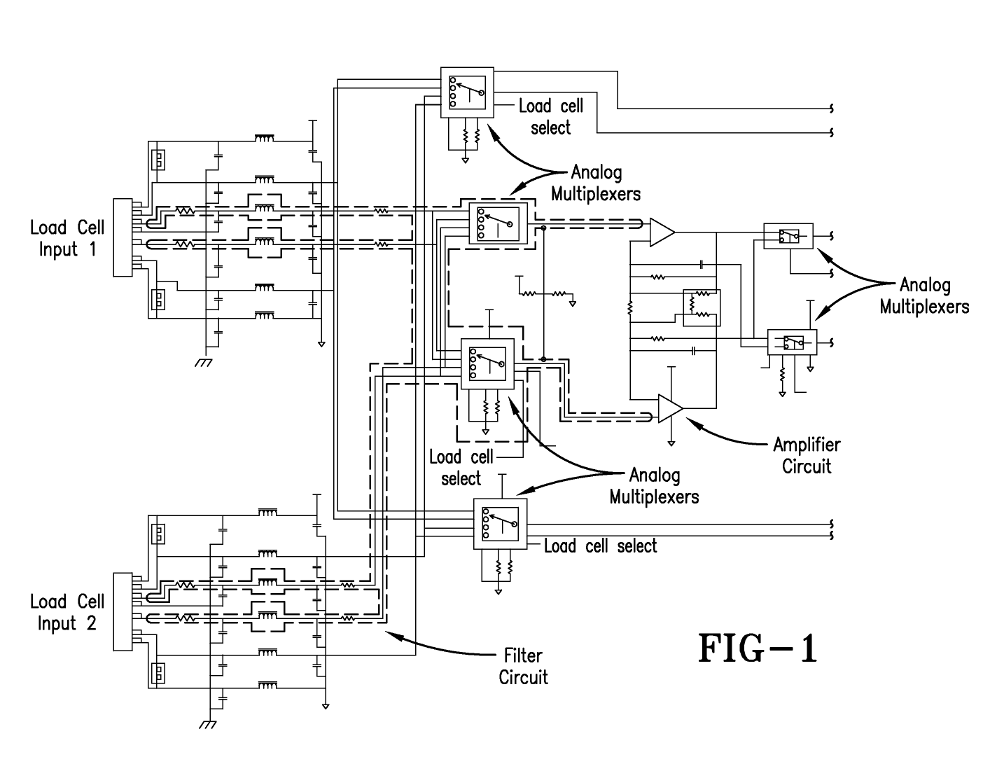

FIG. 1 illustrates one embodiment of the circuit of the present invention. Three pairs of analog multiplexers constantly shift the amplifiers from the positive side of the circuit to the negative side. This effectively cancels out the majority of the drift due to temperature changes and noise. In this circuit, the additional inputs of the multiplexers allow it to shift to an entirely different set of inputs without losing the advantages of the chopper effect or drifting significantly with temperature change. Sections of the ADC circuit, i.e. precision amplifiers and gain resisters, need not be duplicated to achieve additional channels. The circuit shown has two inputs (e.g., load cells), however, it is appreciated that this concept can be used for a greater number of inputs with little increase in cost.

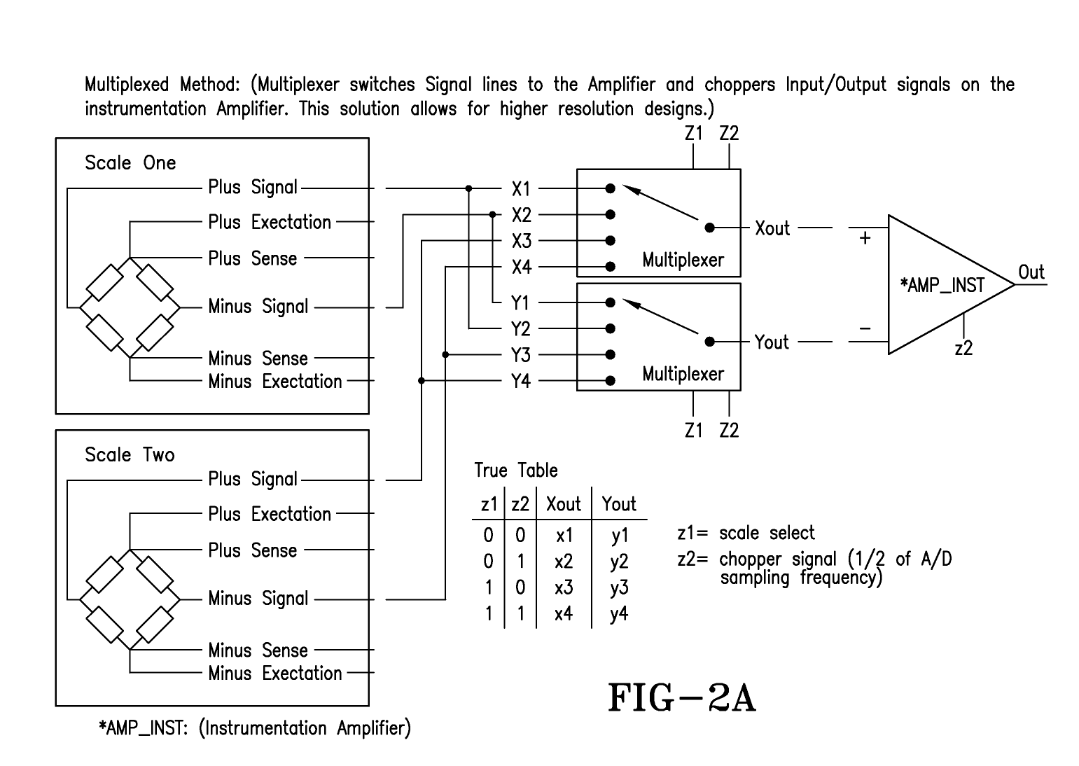

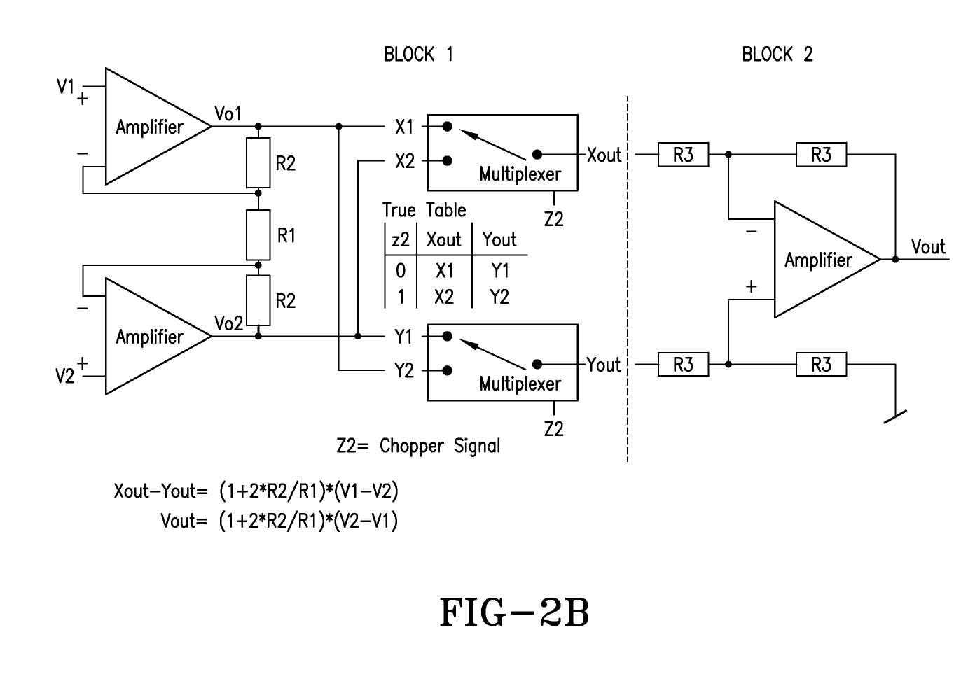

FIG. 2A (top figure) illustrates a diagram of the connections from a first scale (“scale one”) having a Wheatsone circuit and a second scale (“scale two”) also having a Wheatsone circuit to two signal multiplexers. As depicted, the positive (plus) signal from the first scale is connected to the X1 input of the first multiplexer and the input Y2 of the second multiplexer. The negative (minus) signal from the first scale is connected to the X2 input of the first multiplexer and the Y1 input of the second multiplexer. Similarly, the positive (plus) signal from the second scale is connected to the X3 input of the first multiplexer and the input Y4 of the second multiplexer. The negative (minus) signal from the second scale is connected to the X4 input of the first multiplexer and the Y3 input of second multiplexer. Control inputs Z1 is connected to a load scale select signal and Z2 is connected to a chopper signal, which in the preferred embodiment, is half of the ADC sampling frequency. The truth table in FIG. 2A illustrates the output of the multiplexers based on the state of the control signals. For example, Z1=0 selects the scale one inputs of the multiplexers and the chopper input Z2 switches the signals back and forth from the positive to negative side as it toggles back and forth.

FIG. 2B (bottom figure) illustrates preferred embodiments of the chopper instrumentation amplifier circuit build out of discrete components of the present invention. Again, the chopper control signal is connected to multiplexer outputs to control the signal output from the amplifier. The circuit shown in Block 1 amplifies the two input signals V1 and V2 with the second part of the chopper circuit. The circuit in Block 2 represents a standard subtraction circuit design of the instrumentation amplifier. The output of the instrumentation amplifier is connected to the input of the ADC circuit. The circuit in Block 2 is only needed if a single channel ADC is used. In the preferred embodiment, a two channel ADC is used and the subtraction of the signals is built into the digital domain.

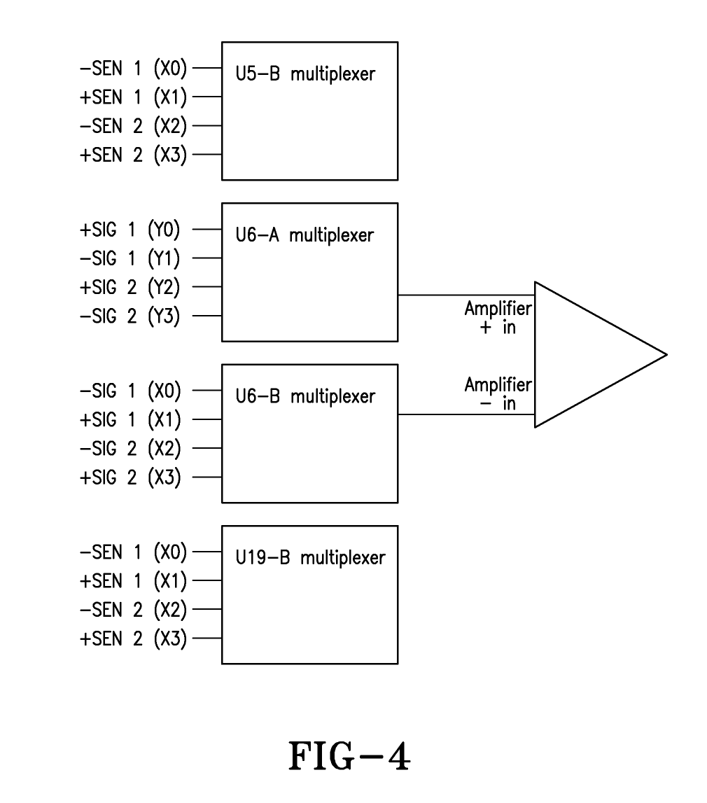

FIG. 4 illustrates a high level diagram of one embodiment of the connections between scale one (load cell) and scale two (load cell) with the input multiplexers. The Excitation signals and Sense signals are fed into multiplexers and switched based on the load scale select as previously discussed. These signals are the reference voltages used by the ADC circuit to convert the instrumentation amplifier output signal into the digital domain.

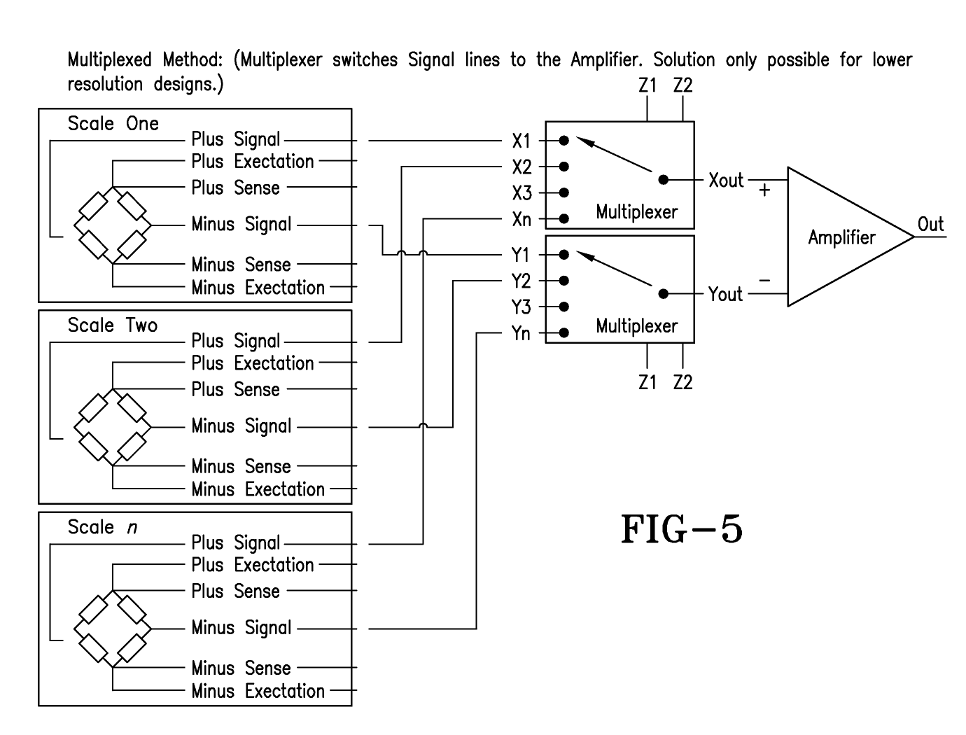

FIG. 5 illustrates another embodiment of a multiplexed ADC circuit, which is preferably used for lower resolution designs.

While certain embodiments of the present invention are described in detail above, the scope of the invention is not to be considered limited by such disclosure, and modifications are possible without departing from the spirit of the invention.

What is claimed is:

1. A system for converting or amplifying signals from a plurality of load cells, comprising:
a first multiplexer circuit electrically connected to the plurality of load cells to receive output signals from the load cells;
an amplifier circuit electronically connected to the first multiplexer circuit;
a control signal in electrical communication with the first multiplexer circuit for selecting one of the load cells and wherein said system is configured to output signals from the selected load cell; and
wherein the system is configured to shift the amplifier circuit from a positive side to a negative side.

2. The system according to claim 1, further comprising:
a chopper signal in electrical communication with the first multiplexer circuit for shifting the amplifier circuit from a positive side to a negative side.

3. The system according to claim 1, wherein the amplifier circuit is an analog to digital converter circuit.

4. The system according to claim 1, wherein the control signal originates from a load cell operator station wherein a load cell operator can switch between two or more load cells by the touch of a button.

5. The system according to claim 1, wherein the amplifier circuit is a precision sigma-delta analog to digital converter.

6. The system according to claim 1, wherein the first multiplexer circuit is comprised of a plurality of multiplexers, one for each of the load cells connected to the system.

7. The system according to claim 2, further comprising:
a second multiplexer circuit connected to an output of the amplifier circuit; and
wherein the chopper signal is in electrical communication with the second multiplexer circuit and controls the signal output from the second multiplexer circuit.

8. A system for converting or amplifying signals from a plurality load cells, comprising:
a first multiplexer circuit electrically connected to the plurality of load cells to receive output signals from the load cells;
an amplifier circuit electronically connected to the first multiplexer circuit;
a control signal in electrical communication with the first multiplexer circuit for selecting one of the load cells and wherein said system is configured to output signals from the selected load cell;
a chopper signal in electrical communication with the first multiplexer circuit for shifting the amplifier circuit from a positive side to a negative side;
a second multiplexer circuit connected to an output of the amplifier circuit; and
wherein the chopper signal is in electrical communication with the second multiplexer circuit and controls the signal output from the second multiplexer circuit.

9. The system according to claim 8, wherein the amplifier circuit is an analog to digital converter circuit.

10. The system according to claim 8, wherein the control signal originates from a load cell operator station wherein a load cell operator can switch between two or more load cells by the touch of a button.

11. The system according to claim 8, wherein the amplifier circuit is a precision sigma-delta analog to digital converter.

12. The system according to claim 8, wherein the first multiplexer circuit is comprised of a plurality of multiplexers, one for each of the load cells connected to the system.

13. A method for amplifying signals from a plurality load cells, comprising the steps of:
receiving signals output from a plurality of load cells at a first multiplexer circuit;
providing an amplifier circuit electronically connected to the first multiplexer circuit;
providing a control signal in electrical communication with the first multiplexer circuit for selecting one of the load cells;
outputting signals from the selected load cell at the output of the first multiplexer circuit; and
providing a chopper signal for shifting the amplifier circuit from a positive side to a negative side.

14. The system according to claim 13, wherein the amplifier circuit is an analog to digital converter circuit.

15. The system according to claim 13, wherein the control signal originates from a load cell operator station wherein a load cell operator can switch between two or more load cells by the touch of a button.

16. The system according to claim 13, wherein the amplifier circuit is a precision sigma-delta analog to digital converter.

17. The system according to claim 13, wherein the first multiplexer circuit is comprised of a plurality of multiplexers, one for each of the load cells connected to the system.

18. The system according to claim 13, further comprising:
providing a second multiplexer circuit connected to an output of the amplifier circuit; and
providing the chopper signal to the second multiplexer circuit for controlling the signal output from the second multiplexer circuit.
